(19) United States
(12) Patent Application Publication
(10) Pub. No.: US 2022/0319809 A1
(43) Pub. Date: Oct. 6, 2022

(54) PLASMA PROCESSING APPARATUS

(71) Applicant: Hitachi High-Tech Corporation, Minato-ku, Tokyo (JP)

(72) Inventors: Taku Iwase, Tokyo (JP); Naoyuki Kofuji, Tokyo (JP); Yasushi Sonoda, Tokyo (JP); Yusuke Nakatani, Tokyo (JP); Motohiro Tanaka, Tokyo (JP)

(21) Appl. No.: 17/273,838

(22) PCT Filed: Dec. 23, 2019
(86) PCT No.: PCT/JP2019/050413

§ 371 Date: Mar. 5, 2021

(51) Int. Cl. H01J 37/32

(52) U.S. Cl. CPC H01J 37/3266; H01J 37/32091; H01J 37/32651

(57) ABSTRACT

An object of the invention is to provide a plasma processing apparatus capable of both isotropic etching in which a flux of ions to a sample is reduced and anisotropic etching in which ions are incident on a sample in the same chamber. For this purpose, the invention includes: a processing chamber in which a sample is subjected to plasma processing; a radio frequency power source configured to supply radio frequency power for generating plasma through a first member of a dielectric material disposed above the processing chamber; a magnetic field forming mechanism configured to form a magnetic field inside the processing chamber; a sample stage where the sample is placed; and a second member disposed between the first member and the sample stage and having a through hole formed therein, in which the through hole is formed at a position where a distance thereof from a center of the second member is a predetermined distance or more, and a distance from the first member to the second member is a distance such that a density of plasma generated between the first member and the second member is a cutoff density or higher.

### TECHNICAL FIELD

The present invention relates to a plasma processing apparatus.

### BACKGROUND ART

In recent years, with an increase in precision of semiconductor device processing, a dry etching apparatus is required to have both a function of irradiation both ions and radicals for processing and a function of irradiation only radicals for processing.

For example, PTL 1 describes “a plasma processing apparatus comprising: a processing chamber in which a sample is subjected to plasma processing; a radio frequency power source configured to supply radio frequency power for generating plasma in the processing chamber; a sample stage where the sample is placed; a shielding plate configured to shield incidence of ions generated from the plasma into the sample stage and disposed above the sample stage; and a controller configured to selectively perform one control for generating plasma above the shielding plate and another control for generating plasma below the shielding plate” (claim 1 of PTL 1).

### CITATION LIST

### Patent Literature

PTL 1: WO 2016/190036

### SUMMARY OF INVENTION

### Technical Problem

In the plasma processing apparatus described in PTL 1, a vertical position where the shielding plate is provided is not considered, and thus even if it is desired to generate plasma only above the shielding plate, microwaves oscillated from the radio frequency power source may pass through the shielding plate and generate plasma below the shielding plate. Therefore, for example, even when it is desired to perform processing by only radicals irradiating, a sample may be irradiated with ions from plasma generated below the shielding plate.

An object of the invention is to provide a plasma processing apparatus capable of both isotropic etching in which a flux of ions to a sample is reduced and anisotropic etching in which ions are incident on a sample in the same chamber.

### Solution to Problem

In order to solve the above problems, the invention includes: a processing chamber in which a sample is subjected to plasma processing; a radio frequency power source configured to supply radio frequency power for generating plasma through a first member of a dielectric material disposed above the processing chamber; a magnetic field forming mechanism configured to form a magnetic field inside the processing chamber; a sample stage where the sample is placed; and a second member disposed between the first member and the sample stage and having a through hole formed therein, in which the through hole is formed at a position where a distance thereof from a center of the second member is a predetermined distance or more, and a distance from the first member to the second member is a distance such that a density of plasma generated between the first member and the second member is a cutoff density or higher.

### Advantageous Effect

It is possible to provide a plasma processing apparatus capable of both isotropic etching in which a flux of ions to a sample is reduced and anisotropic etching in which ions are incident on a sample in the same chamber since electromagnetic waves supplied by an electromagnetic wave supply apparatus are prevented from penetrating below an ion shielding plate, and generation of plasma below the ion shielding plate is prevented during the isotropic etching.

### BRIEF DESCRIPTION OF DRAWINGS

FIG. 1 is a cross-sectional view showing a schematic configuration of a plasma processing apparatus according to an embodiment.

FIG. 2 is a cross-sectional view of an ion shielding plate of the present embodiment.

FIG. 3 is a cross-sectional view showing one of modifications of the ion shielding plate.

FIG. 4 is a distribution diagram showing results of measuring an ion current in an in-plane direction of a sample.

FIG. 5 is a distribution diagram when the ion current is measured by changing a distance between a dielectric window and the ion shielding plate.

### DESCRIPTION OF EMBODIMENTS

Hereinafter, an embodiment of the invention will be described with reference to the drawings.

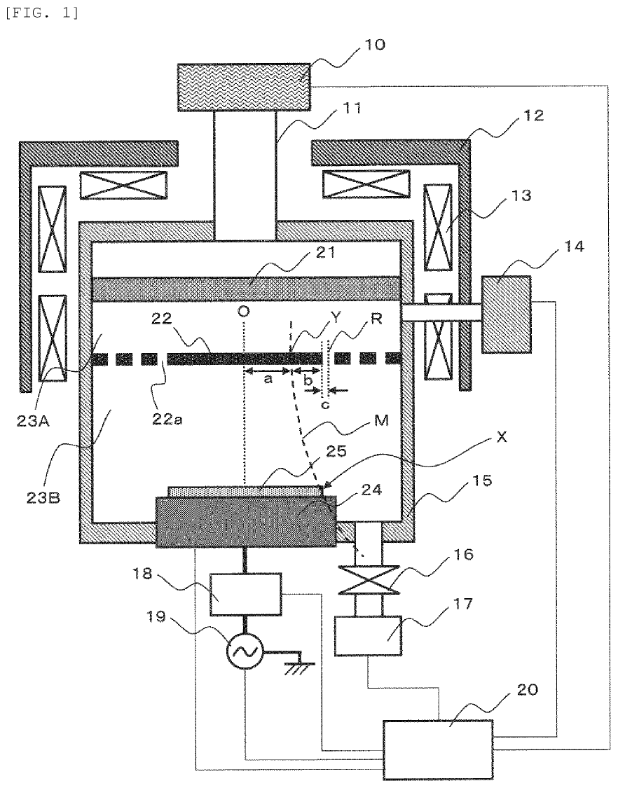

FIG. 1 is a cross-sectional view showing a schematic configuration of a plasma processing apparatus according to the present embodiment. The plasma processing apparatus according to the present embodiment includes a processing chamber 15 in which a sample is subjected to plasma processing, an electromagnetic wave supply apparatus for supplying electromagnetic waves into the processing chamber 15, a magnetic field forming mechanism for forming a magnetic field inside the processing chamber 15, and a gas supply apparatus 14 for supplying process gas into the processing chamber 15.

Here, the processing chamber 15 is a cylindrical container having an opening at an upper portion thereof, and is provided with a dielectric window 21 (a first member), an ion shielding plate 22 (a second member), a sample stage 24, and the like inside. The electromagnetic wave supply apparatus includes a magnetron 10 which is a first radio frequency power source for supplying radio frequency power of microwaves for generating plasma through the dielectric window 21, and a waveguide 11 coupled to the opening of the processing chamber 15. Furthermore, the magnetic field forming mechanism includes a plurality of solenoid coils 13 arranged on an outer periphery of the processing chamber 15, and a yoke 12 disposed so as to surround an outer periphery of each solenoid coil 13.

The dielectric window 21, which is a disk-shaped window portion formed of a dielectric material, is provided above the processing chamber 15, and airtightly seals an inside of the processing chamber 15 while transmitting electromagnetic waves. Here, the processing chamber 15 is connected to a pump 17 via a valve 16, and a decompression processing chamber 23 is formed in a space below the dielectric window 21 by adjusting an opening degree of the valve 16.

The sample stage 24 on which a sample 25 to be processed is placed is horizontally provided on a lower portion of the processing chamber 15. A radio frequency power source 19, which is a second radio frequency power source, is connected to the sample stage 24 via a matcher 18. In addition to the radio frequency power source 19, the magnetron 10, which is the first radio frequency power source, the gas supply apparatus 14, the pump 17, and the like are connected to a controller 20, and are controlled by the controller 20 according to processing steps to be executed.

Furthermore, the ion shielding plate 22 formed of a disk-shaped dielectric material is provided between the dielectric window 21 and the sample stage 24 so as to face the dielectric window 21 and the sample stage 24 . The ion shielding plate 22 divides the decompression processing chamber 23 into upper and lower regions, that is, an upper region 23A defined by the dielectric window 21 and the ion shielding plate 22, and a lower region 23B below the ion shielding plate 22. One end of a gas supply pipe of the gas supply apparatus 14 communicates with the upper region 23A, and supplies the process gas to the upper region 23A. A plurality of through holes 22a for introducing the process gas into the lower region 23B are formed in the ion shielding plate 22.

Next, an operation of performing etching processing in the plasma processing apparatus described above will be described. First, microwaves oscillated by the magnetron 10 constituting the electromagnetic wave supply apparatus are transmitted to the decompression processing chamber 23 in the processing chamber 15 via the waveguide 11. At this time, in the decompression processing chamber 23, a magnetic field is formed by the magnetic field forming mechanism, and the process gas is introduced by the gas supply apparatus 14. Therefore, in the decompression processing chamber 23, the process gas is turned into plasma by electron cyclotron resonance (ECR) due to an interaction between the electromagnetic waves and the magnetic field. As the electromagnetic wave, a microwave having a frequency of, for example, about 2.45 GHz is used. In an ECR plasma processing apparatus as in the present embodiment, plasma is generated in a vicinity of a plane, called an ECR plane, where a magnetic field intensity is 875 Gauss.

In the plasma processing apparatus of the present embodiment, by controlling the magnetic field forming mechanism by the controller 20, an isotropic radical etching mode for generating plasma in the upper region 23A and a reactive ion etching (RIE) mode for generating plasma in the lower region are switched. In the present embodiment, isotropic etching in which a sample is irradiated only with radicals will be described, but isotropic etching in which the sample is irradiated with a neutral gas may be performed.

For example, in the isotropic radical etching mode, the magnetic field forming mechanism is controlled such that the ECR plane is located in the upper region 23A, and the plasma is generated in the upper region 23A. At this time, radicals, ions, and the like are present in the plasma, and the ions also pass through the through holes 22a of the ion shielding plate 22 together with the radicals. However, in the ion shielding plate 22 of the present embodiment, as shown in FIG. 1, since the through hole 22a is formed only at a position where a distance thereof from a center O is larger than a predetermined distance R, the ions reaching the sample can be significantly reduced. Therefore, in the isotropic radical etching mode, only the radicals of the plasma generated in the upper region 23A basically reach the sample 25, and etching is performed.

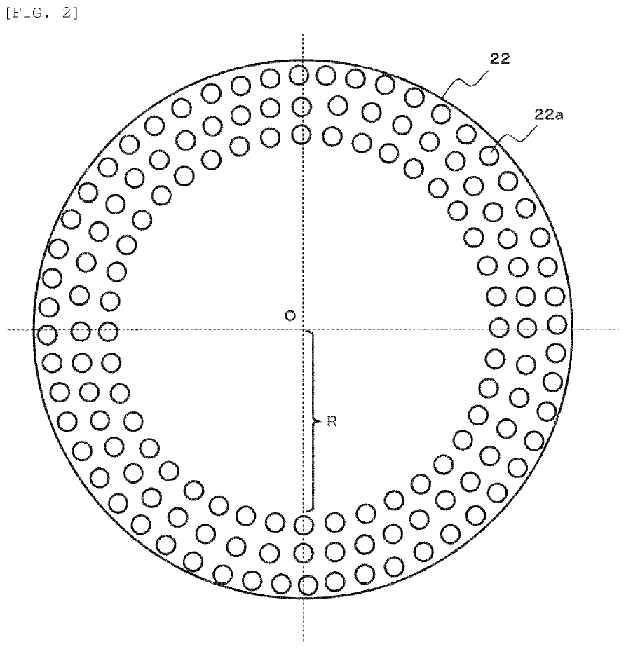

FIG. 2 is a cross-sectional view of the ion shielding plate 22 of the present embodiment. As shown in FIG. 2, in the ion shielding plate 22 of the present embodiment, the through hole 22a is formed in a region where the distance thereof from the center O is the predetermined distance R or more. As will be described later, it is important to shield a region having a smaller inner diameter than the predetermined distance R, and various modifications can be considered for a shape, a size, arrangement, and the like of the through hole 22a provided at a position where the distance thereof from the center O is the predetermined distance R or more.

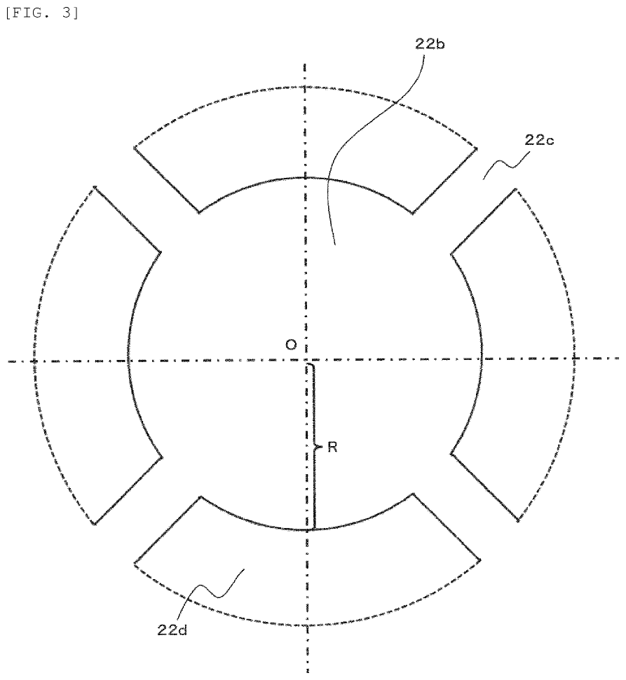

FIG. 3 is a cross-sectional view showing one of modifications of the ion shielding plate 22. In this modification, the ion shielding plate 22 includes a circular shielding portion 22b having a radius of the predetermined distance R or more from the center O, a plurality of radial shielding portions 22c extending radially from the circular shielding portion 22b to an outer diameter side, and a plurality of through portions 22d formed between the plurality of radial shielding portions 22c. The ion shielding plate 22 of this modification has a large total area of the through portions 22d, and thus is suitable a case when it is desired to irradiate the sample 25 with a large number of radicals.

Here, a basis of the predetermined distance R will be described with reference to FIG. 1. A magnetic force line M indicated by a broken line in FIG. 1 is a magnetic force line in contact with an outer end portion X of the sample 25 among magnetic force lines of the magnetic field formed by the magnetic field forming mechanism. A point Y in FIG. 1 indicates a point at which the magnetic force line M intersects with the ion shielding plate 22. A distance from the center O to the point Y is defined as a, and a radius of the through hole is defined as “c”. Furthermore, ions passing through the through hole 22a undergo a cyclotron motion along the magnetic force lines formed by the magnetic field forming mechanism, and a Larmor radius at that time is defined as b. The Larmor radius b is represented by mv/qB when a magnetic flux density is B, an ion velocity in a direction perpendicular to the magnetic flux density is v, an ion mass is m, and an ion charge is q. For example, when Xe+ ions are used in the present embodiment, the Larmor radius is about 10 mm.

Under these conditions, in the present embodiment, the predetermined distance R is set to (a+b+c). Thus, the ions moving from the through hole 22a to the lower region 23B on the outer diameter side of the predetermined distance R are all deflected to an outside of the outer end portion X of the sample 25. In this way, by determining the predetermined distance R in consideration of the cyclotron motion of the ions after passing through the through hole 22a, a flux of the ions to the sample 25 in the isotropic radical etching mode can be reduced as much as possible even when the mass of the ions is large and the Larmor radius is large.

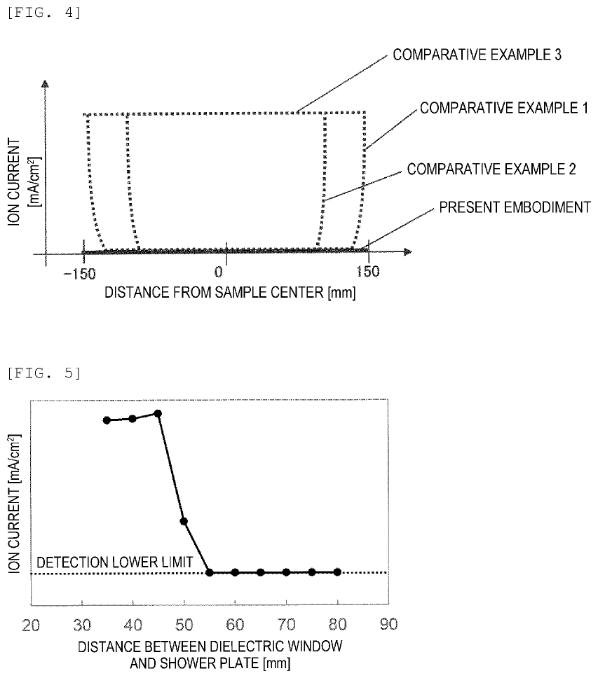

FIG. 4 shows distribution by measuring a value of an ion current flowing when a Xe gas is turned into plasma in an in-plane direction of the sample 25 having a diameter of 300 mm in a case of the present embodiment and a plurality of comparative examples. Here, Comparative Example 1 is an example in which a through hole is provided at a slightly inner diameter side than a region having a radius of the predetermined distance R, Comparative Example 2 is an example in which a through hole is provided also on an inner diameter side than in Comparative Example 1, and Comparative Example 3 is an example in which an ion shielding plate itself is eliminated. As shown in FIG. 4, it can be seen that in the present embodiment, the ion current is very small in an entire region of the sample 25, whereas in Comparative Example 1, the ion current is large at the outer end portion of the sample 25, in Comparative Example 2, the ion current is large in an outer portion of the sample 25, and in Comparative Example 3, the ion current is large in the entire region of the sample 25. In other words, it can be seen that in the comparative examples, the flux of the ions to the sample 25 cannot be prevented.

In the present embodiment, no through hole is provided at a position where a distance from the center O of the ion shielding plate 22 is smaller than the predetermined distance R, but a through hole may be provided to a certain extent as long as it is a through hole through which ions do not easily pass. As the through hole through which the ions do not easily pass, for example, a through hole formed obliquely with respect to a vertical direction, an elongated through hole having a high aspect ratio and the like can be considered. In any case, when 90% or more of the total area of the openings formed in the ion shielding plate 22 is occupied by the through holes located on an outer side than the region having a radius of the predetermined distance R, the flux of the ions can be sufficiently reduced. In the present embodiment, the predetermined distance R is set to (a+b+c), but when the predetermined distance R is (b+c) or more, that is, a sum of a Larmor radius of the ions and a radius of the through hole 22a or more, a certain degree of effect can be expected.

Furthermore, a position of the through hole 22a may be defined by a distance from an outer edge of the ion shielding plate 22, instead of the distance from the center O of the ion shielding plate 22. For example, a plurality of openings may be formed along a circumferential direction in a region from the outer edge of the ion shielding plate 22 to a predetermined distance S. Also in this case, it is desirable not to form an opening on an inner diameter side than a region from the outer edge to the predetermined distance S described above.

By the way, in the isotropic radical etching mode, even if ions in plasma generated in the upper region 23A are shielded by using the ion shielding plate 22 having the through hole 22a as described above, when plasma is generated in the lower region 23B, ions in the plasma in the lower region 23B may reach the sample 25. Therefore, in the present embodiment, a distance from the dielectric window 21 to the ion shielding plate 22 is set such that a density of the plasma generated in the upper region 23A is a cutoff density or higher. Specifically, the distance from the dielectric window 21 to the ion shielding plate 22 is set to 55 mm or more. Thus, it becomes difficult for the microwaves to pass below the ion shielding plate 22, and as a result, it becomes possible to prevent generation of the plasma in the lower region 23B.

In FIG. 5, when the distance from the dielectric window 21 to the ion shielding plate 22 is changed experimentally, an ion current flowing into a plurality of locations in the sample 25 is measured, and an average value thereof is shown. From results shown in FIG. 5, it can be seen that when the distance from the dielectric window 21 to the ion shielding plate 22 is 55 mm or more, plasma can be generated only in the upper region 23A.

Next, a case of an RIE mode will be described. In this case, the magnetic field forming mechanism is controlled such that the ECR plane is located in the lower region 23B, and plasma is generated in the lower region 23B. Here, in the present embodiment, since not only the dielectric window 21 but also the ion shielding plate 22 is formed of a dielectric material, microwaves supplied from the waveguide 11 are easily introduced into the lower region 23B. As a specific material of the dielectric window 21 and the ion shielding plate 22, it is desirable to use quartz that efficiently transmits microwaves and has plasma resistance, but alumina, yttria, or the like may also be used. It is desirable not to provide a further plate-shaped member such as quartz below the flat ion shielding plate 22.

When plasma is generated in the lower region 23B in the RIE mode, both radicals and ions reach the sample 25, and the etching processing is performed. By supplying the radio frequency power from the radio frequency power source 19 to the sample stage 24, the ions in the plasma in the lower region 23B are accelerated. Therefore, by controlling the radio frequency power source 19 by the controller 20, an energy of ion irradiation can be adjusted from several 10 eV to several keV.

### REFERENCE SIGN LIST

10 magnetron

11 waveguide

12 yoke

13 solenoid coil

14 gas supply apparatus

15 processing chamber

16 valve

17 pump

18 matcher

19 radio frequency power source

20 controller

21 dielectric window

22 ion shielding plate

22a through hole

23 decompression processing chamber

23A upper region

23B lower region

24 sample stage

25 sample

1. A plasma processing apparatus, comprising:
a processing chamber in which a sample is subjected to plasma processing;
a radio frequency power source configured to supply radio frequency power for generating plasma through a first member of a dielectric material disposed above the processing chamber;
a magnetic field forming mechanism configured to form a magnetic field inside the processing chamber;
a sample stage where the sample is placed; and
a second member disposed between the first member and the sample stage and having a through hole formed therein, wherein
the through hole is formed at a position where a distance thereof from a center of the second member is a predetermined distance or more, and
a distance from the first member to the second member is a distance such that a density of plasma generated between the first member and the second member is a cutoff density or higher.

2. The plasma processing apparatus according to claim 1, wherein
the predetermined distance is a distance defined based on a Larmor radius of ions.

3. The plasma processing apparatus according to claim 2, wherein
a distance from the first member to the second member is 55 mm or more.

4. The plasma processing apparatus according to claim 2, wherein
a value of the predetermined distance is a sum of a Larmor radius of the ions and a radius of the through hole.

5. The plasma processing apparatus according to claim 3, wherein
a value of the predetermined distance is a sum of a Larmor radius of the ions and a radius of the through hole.

6. The plasma processing apparatus according to claim 5, wherein
the radio frequency power is radio frequency power of microwaves,
the second member is a quartz flat plate, and
the through hole is not formed in a region having a radius of the predetermined distance centered on a center of the second member.

7. A plasma processing apparatus, comprising:
a processing chamber in which a sample is subjected to plasma processing;
a radio frequency power source configured to supply radio frequency power for generating plasma through a first member of a dielectric material disposed above the processing chamber;
a magnetic field forming mechanism configured to form a magnetic field inside the processing chamber;
a sample stage where the sample is placed; and
a second member disposed between the first member and the sample stage, wherein
the second member is formed with a plurality of openings along a circumferential direction in a region from an outer edge of the second member to a predetermined distance, and
a distance from the first member to the second member is a distance such that a density of plasma generated between the first member and the second member is a cutoff density or higher.

8. The plasma processing apparatus according to claim 7, wherein
the predetermined distance is a distance defined based on a Larmor radius of ions.

9. The plasma processing apparatus according to claim 8, wherein
a distance from the first member to the second member is 55 mm or more.

10. The plasma processing apparatus according to claim 9, wherein
the radio frequency power is radio frequency power of microwaves,
the second member is a quartz flat plate, and
the opening is not formed in a region having a radius of the predetermined distance centered on a center of the second member.
